(19) United States
(12) Patent Application Publication
(10) Pub. No.: US 2026/0206585 A1
(43) Pub. Date: Jul. 16, 2026

(54) METAL-CERAMIC SUBSTRATE WITH CONTACT AREA

(71) Applicant: Heraeus Electronics GmbH & Co. KG, Hanau (DE)

(72) Inventors: Richard WACKER, Hanau (DE); Fabian SIPOS, Chisoda (RO); Ciprian BATISTA, Chisoda (RO); Andrei-Stefan LEAH, Chisoda (RO)

(21) Appl. No.: 19/032,344

(22) Filed: Jan. 20, 2025

(30) Foreign Application Priority Data
Jan. 24, 2024 (EP) 24153587.1

(51) Int. Cl. H10W 40/25

(52) U.S. Cl. CPC H10W 40/255

(57) ABSTRACT

A metal-ceramic substrate and an electronic component comprising a metal-ceramic substrate, the substrate comprising: a) a ceramic body which comprises a main boundary surface, b) a metal layer which comprises a main boundary surface, wherein the metal layer is bonded over the surface to the ceramic body, and wherein the metal layer comprises a structuring region which comprises (i) solid material in regions and (ii) non-solid material in regions, and c) a silver-comprising contact region arranged on the metal layer, wherein in a cross-section through the metal-ceramic substrate perpendicular to the main boundary surface of the ceramic body, the structuring region has a geometry, wherein the following requirement is met:

A (BCD_{solid})/A (BCDₜₒₜₐₗ)>70%, where A (BCDₜₒₜₐₗ) and A (BCD_{solid}) are described in the specification.

### CROSS-REFERENCE TO RELATED APPLICATIONS

This application claims priority pursuant to 35 U.S.C. § 119 (a) to European Application No. 24153587.1, filed Jan. 24, 2024, which application is incorporated herein by reference in its entirety.

### FIELD OF THE INVENTION

The present invention relates to a metal-ceramic substrate and to an electronic component comprising a metal-ceramic substrate.

### BACKGROUND OF THE INVENTION

Metal-ceramic substrates play an important role in the field of power electronics. They are a crucial element when building electronic components and ensure rapid dissipation of large quantities of heat during operation of said components. Metal-ceramic substrates typically consist of a ceramic layer and a metal layer which is bonded to the ceramic layer.

Several methods are known from the prior art for bonding the metal layer to the ceramic layer. In the so-called DCB (“direct copper bonding”) method, a copper foil is provided superficially with a copper compound (usually copper oxide), which has a lower melting point than copper, by reacting copper with a reactive gas (usually oxygen). When the copper foil treated in this way is applied to a ceramic body and the composite is heated, the copper compound melts and wets the surface of the ceramic body so that a stable cohesive bond is achieved between the copper foil and the ceramic body. This method is described, for example, in U.S. Pat. No. 3,744,120 A or DE 2319854 C2.

In an alternative method, metal foils can be bonded to ceramic bodies at temperatures of approximately 650 to 1000° C., wherein a special solder is used which contains a metal having a melting point of at least 700° C. (usually silver) and an active metal. The role of the active metal is to react with the ceramic material and to thus facilitate a bonding of the ceramic material to the remaining solder, forming a reaction layer, while the metal having a melting point of at least 700° C. serves to bond said reaction layer to the metal foil. For example, JP4812985 B2 proposes bonding a copper foil to a ceramic body using a solder containing 50 to 89 weight percent silver, as well as copper, bismuth and an active metal. With this method, it is possible to reliably attach the copper foil to the ceramic body. Alternatively, silver-free solders can be used to bond metal foils to ceramic bodies. These solders are based, for example, on high-melting metals (in particular copper), low-melting metals (such as bismuth, indium or tin), and active metals (such as titanium). Such a technique is proposed, for example, in DE 102017114893 A1. This technique basically results in a new, independent class of compounds, since the basis of the solders used is formed by another metal (copper instead of silver), which leads to changed material properties and results in an adaptation with regard to the other solder components and modified joining conditions.

When constructing electronic components, metal-ceramic substrates are usually equipped with a chip. In order to equip the metal-ceramic substrate with a chip, it is usually necessary that the region of the metal-ceramic substrate to be equipped with the chip is provided with a silver-containing contact region. By providing the silver-containing contact region, the chip can be more easily connected to the metal-ceramic substrate using common processes such as sintering or soldering. To create the contact region, the metal-ceramic substrate is usually first treated in regions with an etching solution in order to form the desired structuring. The contact region is then provided by applying, in regions, a silver-containing coating to the surface of the structured metal-ceramic substrate.

The metal-ceramic substrates produced in this way are usually exposed to high temperature changes during operation as part of electronic components. While during breaks in operation-depending on the environment—the temperatures can be, for example, −20° C. or less, the temperature of the metal-ceramic substrates can easily rise to over 150° C. during operation. The metal-ceramic substrates are regularly exposed to these temperature differences. Due to the different thermal expansion coefficients of the metal and the ceramic, repeated temperature changes can lead to the metal layer detaching from the ceramic body (peeling), which results in a loss of performance. Therefore, high thermal shock resistance is a key criterion for the suitability of metal-ceramic substrates for applications in electronics, especially in power electronics.

It would therefore be desirable to further increase the thermal shock resistance of metal-ceramic substrates.

### BRIEF DESCRIPTION OF THE DRAWINGS

FIG. 1 is a schematic representation of a generic metal-ceramic substrate.

FIG. 2 is a schematic representation of a metal-ceramic substrate according to the invention with a structuring region, wherein the solid material in the region adjacent to the upper half of the contour line has a higher silver content than in the region adjacent to the lower half of the contour line.

FIG. 3 is an image of a part of a cross-section through a metal-ceramic substrate according to the invention.

FIG. 4 is a light microscopic image of the cross-section of a detail of structuring region of the copper layer of a copper-ceramic substrate according to Example 1.

FIG. 5 is a light microscopic image of the cross-section of a detail of a structuring region of the copper layer of a copper-ceramic substrate according to Comparative Example 1.

### DETAILED DESCRIPTION

An object of the present invention is therefore to provide a metal-ceramic substrate which has an increased resistance to thermal shock.

This object is achieved by the metal-ceramic substrate of claim 1. The invention therefore provides a metal-ceramic substrate comprising
a) a ceramic body which comprises a main boundary surface,
b) a metal layer which comprises a main boundary surface, wherein the metal layer is bonded over the surface to the ceramic body, and wherein the metal layer comprises a structuring region which comprises
   (i) solid material in regions and
   (ii) non-solid material in regions
and
c) a silver-comprising contact region arranged on the metal layer,
wherein
in a cross-section through the metal-ceramic substrate perpendicular to the main boundary surface of the ceramic body, the structuring region has a geometry that satisfies the following requirement:

$$A ( {BCD}_{s o l i d} ) / A ( {BCD}_{t otal} ) > 70 \% ,$$

where
A (BCDₜₒₜₐₗ) is the total area of the triangle described by the points B, C and D, and
A (BCD_{solid}) is the area of the triangle described by the points B, C and D that is occupied by solid material,
wherein points B, C and D are determined as follows:
1. the best-fit line between the ceramic body and the metal layer is determined;
2. the contour line is determined that separates the solid material from the non-solid material;
3. on a perpendicular to the best-fit line, at a distance of 150 μm from the best-fit line, point A is determined at which the perpendicular to the best-fit line intersects the contour line;
4. on a perpendicular to the best-fit line, at a distance of 80 μm from the best-fit line, point B is determined at which the perpendicular to the best-fit line intersects the contour line;
5. on a straight line passing through points A and B, point C is determined at which the straight line intersects the best-fit line; and
6. on a perpendicular to the best-fit line, which passes through point B, point D is determined at which the perpendicular intersects the best-fit line; and
wherein the contour line extends from the main boundary surface of the metal layer to the main boundary surface of the ceramic body, wherein the contour line comprises an upper half and a lower half, wherein the upper half of the contour line extends from the main boundary surface of the metal layer towards the main boundary surface of the ceramic body and the lower half of the contour line extends from the main boundary surface of the ceramic body towards the main boundary surface of the metal layer, and wherein the solid material in the region adjacent to the upper half of the contour line has a higher silver content than in the region adjacent to the lower half of the contour line.

Furthermore, the invention relates to an electronic component comprising such a metal-ceramic substrate.

The metal-ceramic substrate according to the invention comprises a ceramic body which comprises a main boundary surface.

The ceramic body is preferably a body formed from ceramic. The body can have any geometry, but is preferably designed as a cuboid. The ceramic body comprises boundary surfaces, in the case of a cuboid six boundary surfaces. The main boundary surface is preferably referred to herein as the boundary surface (very particularly preferably the boundary surface with the largest area) which is bonded over the surface to the metal layer. The main boundary surface is particularly preferably the boundary surface (very particularly preferably the boundary surface with the largest area) which is bonded over the surface to the metal layer which comprises a structuring region, and very particularly preferably the boundary surface (in particular the boundary surface with the largest area) which is bonded over the surface to the metal layer on which a contact region comprising silver is arranged. The main boundary surface preferably lies in the main extension plane of the ceramic body or runs parallel to it. Accordingly, the main extension plane of the ceramic body is preferably understood to be a plane that runs parallel to the main boundary surface of the ceramic body or encloses it.

The ceramic of the ceramic body is preferably an insulating ceramic. According to a preferred embodiment, the ceramic is selected from the group consisting of oxide ceramics, nitride ceramics, and carbide ceramics. According to a further preferred embodiment, the ceramic is selected from the group consisting of metal oxide ceramics, silicon oxide ceramics, metal nitride ceramics, silicon nitride ceramics, boron nitride ceramics, and boron carbide ceramics. According to a particularly preferred embodiment, the ceramic is selected from the group consisting of aluminum nitride ceramics, silver nitride ceramics, and aluminum oxide ceramics (such as ZTA (“zirconia toughened alumina”) ceramics). According to a further very particularly preferred embodiment, the ceramic body consists of (1) at least one element selected from the group consisting of silicon and aluminum, (2) at least one element selected from the group consisting of oxygen and nitrogen, optionally (3) at least one element selected from the group consisting of (3a) rare earth metals, (3b) metals of the second main group of the periodic table of elements, (3c) zirconium, (3d) copper, (3e) molybdenum and (3f) silicon, and optionally (4) unavoidable impurities. According to yet another very particularly preferred embodiment, the ceramic body is free of bismuth, gallium, and zinc.

The ceramic body preferably has a thickness in the range of 0.05-10 mm, more preferably a thickness in the range of 0.1-5 mm, and particularly preferably a thickness in the range of 0.15-3 mm.

The metal-ceramic substrate according to the invention comprises a metal layer which comprises a main boundary surface, wherein the metal layer is bonded over the surface to the ceramic body, and wherein the metal layer comprises a structuring region which comprises (i) solid material in regions and (ii) non-solid material in regions.

The metal layer comprises boundary surfaces. The metal layer comprises a main boundary surface. The main boundary surface is preferably referred to herein as the boundary surface (very particularly preferably the boundary surface with the largest area) which faces away from the ceramic body. Consequently, the main boundary surface is preferably referred to as the boundary surface (very particularly preferably the boundary surface with the largest area) on which the silver-comprising contact region is arranged. The main boundary surface preferably lies in the main extension plane of the metal layer or runs parallel to it. Accordingly, the main extension plane of the metal layer is preferably understood to be a plane that runs parallel to the main boundary surface of the metal layer or encloses it. The main boundary surface of the metal layer preferably runs parallel to the main boundary surface of the ceramic body and is particularly preferably spaced apart from it.

The metal layer is preferably cohesively bonded to the ceramic body. According to a preferred embodiment, the metal layer is bonded to the ceramic body via a DCB (Direct Copper Bonding) process. According to a further preferred embodiment, the metal layer is bonded to the ceramic body via a brazing process. The brazing process can, for example, be an AMB (Active Metal Brazing) process, preferably using silver-free brazing alloys (the silver content is then, for example, less than 1.0 weight percent based on the solids content of the brazing alloy) or silver-containing brazing alloys (the silver content is then, for example, at least 50 weight percent based on the solids content of the brazing alloy). Consequently, the metal layer may also comprise a bonding layer in contact with the ceramic body. The bonding layer can be, for example, a solder layer (in particular a brazing layer) or a diffusion layer.

The metal layer is bonded over the surface to the ceramic body. Accordingly, the metal layer is preferably bonded over the surface to the main boundary surface of the ceramic body. The metal layer is preferably not bonded to the entire main boundary surface of the ceramic body. In particular, it can be provided that the main boundary surface of the ceramic body is larger than the surface of the metal layer bonded to the ceramic body. In these cases, the main boundary surface of the ceramic body protrudes. In addition, the metal layer is preferably structured. Structuring is preferably understood to mean recesses in the metal layer in order to separate individual portions of the metal layer from one another and thus to electrically isolate them. Such structuring is usually created using etching techniques.

Accordingly, the metal layer comprises a structuring region. The structuring region is understood to be a portion of the metal layer that contains a structuring. A structuring is preferably a recess in the metal layer. Consequently, the main boundary surface of the metal layer comprises metal of the metal layer which is interrupted by the recess in the structuring region.

The structuring region comprises a region comprising solid material and a region comprising non-solid material.

The region comprising solid material preferably contains (i) metal of the metal layer (optionally including a bonding layer (if present)) and (ii) metal of the contact region (in particular silver).

The region comprising non-solid material preferably contains gaseous material. Therefore, the non-solid material preferably comprises gaseous material. The non-solid material is preferably gaseous material with which the recess in the metal layer is filled. This gaseous material usually comes from the ambient atmosphere. Preferably, the gaseous material therefore contains at least one element selected from the group consisting of nitrogen, oxygen and noble gases. The gaseous material is very particularly preferably a gas mixture, in particular air.

According to a preferred embodiment, the recess extends in a direction perpendicular to the main boundary surface of the ceramic body from the main boundary surface of the ceramic body to the main boundary surface of the metal layer. The recess preferably forms a channel which is filled to at least 50 percent by volume, more preferably to at least 80 percent by volume, even more preferably to at least 90 percent by volume, particularly preferably to at least 95 percent by volume and very particularly preferably to at least 99 percent by volume, in particular completely, with non-solid material.

The metal layer preferably comprises at least one metal selected from the group consisting of copper, aluminum and molybdenum. According to a particularly preferred embodiment, the metal layer comprises at least one metal which is selected from the group consisting of copper and molybdenum. According to a very particularly preferred embodiment, the metal layer comprises copper. According to a further preferred embodiment, the metal layer consists of copper and unavoidable impurities. According to a further preferred embodiment, the proportion of copper is at least 60 weight percent, more preferably at least 65 weight percent, even more preferably at least 70 weight percent and particularly preferably at least 75 weight percent, in relation to the total weight of the metal layer (preferably including any bonding layer that may be present).

According to a preferred embodiment, the metal layer is produced by cohesively bonding a copper foil (preferably a foil made of high-purity copper) to a ceramic body. According to a preferred embodiment, the bonding can take place via a DCB (Direct Copper Bonding) process or via a brazing process. The brazing process can, for example, be an AMB (Active Metal Brazing) process, preferably using silver-free brazing alloys (the silver content is then, for example, less than 1.0 weight percent based on the solids content of the brazing alloy) or silver-containing brazing alloys (the silver content is then, for example, at least 50 weight percent based on the solids content of the brazing alloy). In this case, the metal layer may comprise, in addition to the copper originating from the copper foil, also metals from a bonding layer, in particular metals from a solder layer (for example a brazing layer) or a diffusion layer.

The metal layer preferably has a thickness in the range of 0.01-10 mm, particularly preferably a thickness in the range of 0.03-5 mm, and very particularly preferably a thickness in the range of 0.05-3 mm.

The metal-ceramic substrate according to the invention comprises a silver-comprising contact region arranged on the metal layer. The contact region preferably serves to facilitate the connection of a chip to the metal layer. Chips are preferably bonded to the metal layer by sintering, soldering or gluing. Since in particular the attachment of chips to the metal of the metal layer of a metal-ceramic substrate is not easily possible, the metal layer is preferably provided with a contact region. The contact region is preferably made of silver or a silver-containing alloy. In the case of a silver-containing alloy, it contains at least 50 weight percent silver, in relation to the weight of the silver alloy. Preferably, a contact region is provided on the metal layer of the metal-ceramic substrate at all positions where the metal-ceramic substrate is later to be populated with chips. The contact region can be formed on the metal layer of the metal-ceramic substrate using different techniques. For example, it is possible to provide the contact region by deposition of a silver-containing layer. The deposition of the silver-containing layer is preferably carried out chemically (for example electrochemically) or physically. The chemical deposition of the silver-containing layer can be carried out, for example, galvanically or currentlessly. Preference is given to chemical deposition of the silver-containing layer currentlessly by applying a silver-containing solution with a charge exchange between the metals, wherein metal of the metal layer partially dissolves while the silver in solution is deposited. According to a preferred embodiment, the silver-containing solution contains a silver salt and particularly preferably silver nitrate. According to a particularly preferred embodiment, the silver-containing solution is an acidic solution of silver nitrate and particularly preferably a nitric acid solution of silver nitrate. The physical deposition of the silver-containing layer can be carried out, for example, by gas phase deposition. Preferred methods for gas phase deposition are in particular electron beam deposition, laser beam deposition, arc discharge deposition or cathode sputtering.

The structuring region of the metal layer of the metal-ceramic substrate has the geometry described herein. The geometry of the structuring region is determined in a cross-section through the metal-ceramic substrate perpendicular to the main boundary surface of the ceramic body.

The structuring region of the metal-ceramic substrate, in a cross-section through the metal-ceramic substrate perpendicular to the main boundary surface of the ceramic body has a geometry that satisfies the following requirement:

$$A ( {BCD}_{s o l i d} ) / A ( {BCD}_{t otal} ) > 70 \% ,$$

where
A (BCDₜₒₜₐₗ) is the total area of the triangle described by the points B, C and D, and
A (BCD_{solid}) is the area of the triangle described by the points B, C and D that is occupied by solid material,

According to a preferred embodiment, the structuring region of the metal-ceramic substrate in a cross-section through the metal-ceramic substrate perpendicular to the main boundary surface of the ceramic body has a geometry that satisfies the ratio A (BCD_{solid})/A (BCDₜₒₜₐₗ)>75%, more preferably >80%, even more preferably >85%, particularly preferably >90% and very particularly preferably >95%.

According to a further preferred embodiment, the structuring region of the metal-ceramic substrate in a cross-section through the metal-ceramic substrate perpendicular to the main boundary surface of the ceramic body has a geometry that satisfies the ratio A (BCD_{solid})/A (BCDₜₒₜₐₗ) is in the range of 75-100%, particularly preferably in the range of 90-100% and most preferably in the range of 95-99%.

To determine the triangle described by points B, C and D, a cross-section of the structuring region of the metal layer of the metal-ceramic substrate is observed. The cross-section runs perpendicular to the main boundary surface of the ceramic body. Preferably, the observation of the cross-section can be carried out by cutting the metal-ceramic substrate perpendicular to the main boundary surface of the ceramic body and taking a picture of the cross-section thus obtained using a scanning electron microscope.

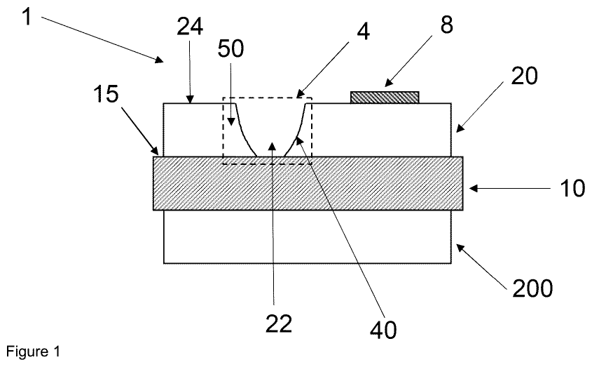

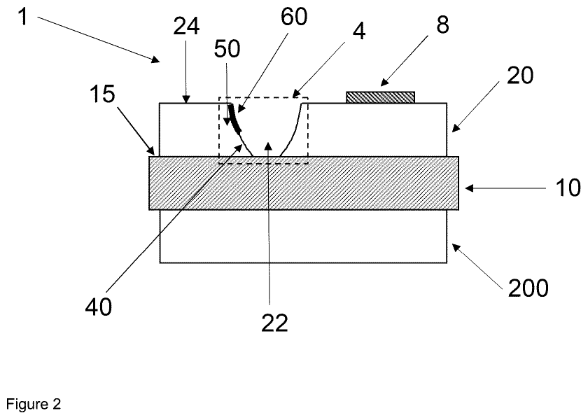

The points B, C and D of the triangle can be determined in the cross-section as described below. For illustration purposes, reference is made to FIGS. 1 and 2 by way of example.

FIG. 1 shows a schematic representation of a generic metal-ceramic substrate;

FIG. 2 shows schematically a metal-ceramic substrate according to the invention with a structuring region, wherein the solid material in the region adjacent to the upper half of the contour line has a higher silver content than in the region adjacent to the lower half of the contour line; and,

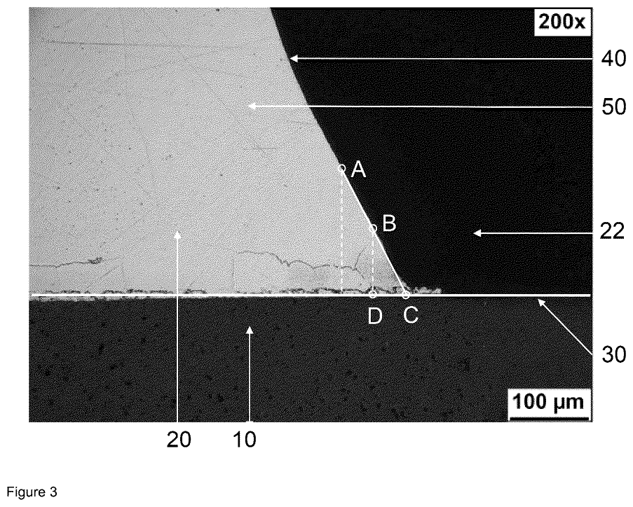

FIG. 3 shows a part of a cross-section through a metal-ceramic substrate according to the invention.

The metal-ceramic substrate 1 shown in FIG. 1 comprises a ceramic body 10. The ceramic body 10 comprises a main boundary surface 15. The metal-ceramic substrate 1 comprises a metal layer 20. The metal layer 20 comprises, on the upper side facing away from the main boundary surface 15 of the ceramic body 10, a main boundary surface 24 parallel to the main boundary surface 15 of the ceramic body 10. The metal layer 20 is bonded over the surface to the main boundary surface 15 of the ceramic body 10. In the embodiment according to FIG. 1, the metal-ceramic substrate 1 further comprises a further metal layer 200 which is bonded over the surface to the ceramic body 10. On the metal layer 20 there is a contact region 8 comprising silver. The metal layer 20 comprises a structuring. This is formed by a recess 22 in the metal layer 20. The recess 22 contains non-solid material. The structuring region 4 comprises, in regions, the metal of the metal layer 20 and the recess 22. Therefore, the structuring region 4 comprises, in regions, solid material 50, which is formed by the metal of the metal layer 20, and non-solid material (for example gaseous material) with which the recess 22 is filled. The gaseous material is usually ambient air. The solid material 50 is separated from the non-solid material of the recess 22 by a contour line 40. The main boundary surface 24 of the metal layer 20 comprises metal of the metal layer 20, which is interrupted by the recess 22 in the structuring region. The recess 22 extends in a direction perpendicular to the main boundary surface 15 of the ceramic body 10 from the main boundary surface 24 of the metal layer 20 to the main boundary surface 15 of the ceramic body 10 and preferably forms a channel which is completely or predominantly filled with non-solid material.

The metal-ceramic substrate shown in FIG. 2 has the same basic structure as the metal-ceramic substrate shown in FIG. 1. The contour line 40 comprises an upper half and a lower half. The upper half of the contour line 40 extends from the main boundary surface 24 of the metal layer 20 in the direction of the main boundary surface 15 of the ceramic body 10. The lower half of the contour line 40 extends from the main boundary surface 15 of the ceramic body 10 in the direction of the main boundary surface 24 of the metal layer 20. The solid material 50 comprises silver 60 in the region adjacent to the upper half of the contour line 40. In the region adjacent to the lower half of the contour line 40, the solid material comprises no or less silver 60.

In the part of a cross-section through a metal-ceramic substrate according to the invention shown in FIG. 3, a portion of a structuring region can be seen. Shown is a region of the ceramic body 10 which is bonded over the surface to a region of a metal layer 20. The contour line 40 separates the solid material 50 from the non-solid material of the recess 22 in the metal layer 20.

The determination of points B and C of the line BC in the cross-section is preferably carried out in several steps:

In a first step, the best-fit line 30 between the ceramic body 10 and the metal layer 20 is determined. For this purpose, the region of the ceramic body 10 and the region of the metal layer 20 are optically determined and the best-fit line 30 is defined as the boundary between the ceramic body 10 and the metal layer 20 that can be observed in the cross-section.

In a second step, the contour line 40 is determined that separates the solid material 50 from the non-solid material of the recess 22. The solid material 50 is determined optically; this is usually the material of the metal layer 20. The non-solid material is also determined visually.

The non-solid material is usually a gaseous material with which the structuring is filled as a recess 22 in the metal layer 20.

In a third step, on a perpendicular to the best-fit line 30, at a distance of 150 μm from the best-fit line 30, point A is determined at which point the perpendicular to the best-fit line 30 intersects the contour line 40.

In a fourth step, on a perpendicular to the best-fit line 30 at a distance of 80 μm from the best-fit line 30, point B is determined at which point the perpendicular to the best-fit line 30 intersects the contour line 40.

In a fifth step, on a straight line passing through points A and B, point C is determined at which the straight line intersects the best-fit line 30.

In a sixth step, on a perpendicular to the best-fit line 30, which passes through point

B, point D is determined at which the perpendicular intersects the best-fit line 30.

The cutting of the metal-ceramic substrate perpendicular to the main boundary surface of the ceramic body and the recording of the cross-section thus obtained through a light microscope (incident light/bright field) are preferably carried out as described below:

In a first step, a cuboid sample blank having a rectangular base in the range of 100 mm² to 400 mm² is first cut out of the metal-ceramic substrate to be examined by sawing using a diamond saw blade at a low rotational speed and using a lubricant (Exakt) perpendicular to a plane spanned by the main boundary surface of the ceramic body of the metal-ceramic substrate. The sample blank accordingly comprises a sample surface which is investigated. This sample surface therefore runs perpendicular to the plane spanned by the main boundary surface of the ceramic body of the metal-ceramic substrate before sawing. It therefore comprises portions on the ceramic body and the metal layer (including the bonding layer optionally provided). The sample blank is first embedded in a casting mold with a low-shrinkage epoxy resin (Caldo-Fix, Struers), wherein the sample surface is oriented perpendicular to the mold wall. The epoxy resin is then cured at 75° C. in a drying cabinet. After curing, the sample surface of the sample blank is mechanically polished with an automated polishing device (Tegrapole, Struers) in order to achieve a roughness of 1 μm or less.

In a second step, a structuring region which comprises solid material in regions and non-solid material in regions is identified in the metal layer using a light microscope (Leica, DM6000M, incident light/bright field) at a magnification of 200× in the analysis zone. Solid material and non-solid material can be clearly distinguished in the structuring region due to the different colors.

The areas A (BCD_{solid}) and A (BCDₜₒₜₐₗ) are preferably determined in a routine manner, for example using image evaluation software (e.g., IMS Client, Imagic).

Preferably, the term “in a cross-section” as used herein refers to a (preferably representative) total of cross-sections, particularly preferably to at least ten cross-sections, very particularly preferably to not more than 20 cross-sections and in particular to ten cross-sections. The cross-sections preferably run parallel to each other and are evenly spaced from each other.

Here, to determine the ratio A (BCD_{solid})/A (BCDₜₒₜₐₗ) for a metal-ceramic substrate to be observed, the following procedure is preferably used:
1. At least ten, particularly preferably ten, different cross-sections of the structuring region are examined;
2. the ratio A (BCD_{solid})/A (BCDₜₒₜₐₗ) is determined for each of these cross-sections; and
3. the ratios A (BCD_{solid})/A (BCDₜₒₜₐₗ) are averaged for each of these cross-sections to obtain the ratio A (BCD_{solid})/A (BCDₜₒₜₐₗ) for the metal-ceramic substrate under observation.

According to a preferred embodiment, the sample standard deviation SSD of the ratio A (BCD_{solid})/A (BCDₜₒₜₐₗ) over at least ten different cross-sections of at least one structuring region of the metal layer, more preferably over no more than 20 different cross-sections of at least one structuring region of a metal layer, and most preferably over ten different cross-sections of at least one structuring region of a metal layer, is not more than 10%, more preferably not more than 7%, particularly preferably not more than 5% and very particularly preferably not more than 2%. The sample standard deviation SSD is determined using the following formula:

$$S S D = \sqrt{\frac{1}{n - 1} {{Σ}_{i - - 1}^{n} ( {X}_{i} - \overline{X} )}^{2}} ,$$

$$where :$$

$$n = number of individual values for the ratio A ( BCD {-}_{solid} ) / A ( BDC {-}_{total} ) ,$$

$${X}_{i} = individual value for the ratio A ( BCD {-}_{solid} ) / A ( BDC {-}_{total} ) , and$$

$$\overline{X} = mean of the individual values for the ratio A ( BCD {-}_{solid} ) / A ( BCD {-}_{total} ) .$$

According to the invention, in a cross section through the metal-ceramic substrate perpendicular to the main boundary surface of the ceramic body, the structuring region has a geometry, wherein the contour line extends from the main boundary surface of the metal layer to the main boundary surface of the ceramic body, wherein the contour line comprises an upper half and a lower half, wherein the upper half of the contour line extends from the main boundary surface of the metal layer towards the main boundary surface of the ceramic body and the lower half of the contour line extends from the main boundary surface of the ceramic body towards the main boundary surface of the metal layer, and wherein the solid material in the region adjacent to the upper half of the contour line has a higher silver content than in the region adjacent to the lower half of the contour line.

According to the invention, the contour line therefore extends from the main boundary surface of the metal layer to the main boundary surface of the ceramic body. The contour line preferably does not extend along the main boundary surface of the ceramic and not along the main boundary surface of the metal layer. Therefore, the contour line preferably extends over a region that does not include the main boundary surface of the ceramic and the main boundary surface of the metal layer.

The contour line comprises an upper half and a lower half. The upper half of the contour line extends from the main boundary surface of the metal layer in the direction of the main boundary surface of the ceramic body. The lower half of the contour line extends from the main boundary surface of the ceramic in the direction of the main boundary surface of the metal layer.

According to the invention, the solid material in the region adjacent to the upper half of the contour line has a higher silver content than in the region adjacent to the lower half of the contour line. According to a preferred embodiment, the ratio of the content of silver in the solid material in the region adjacent to the lower half of the contour line to the content of silver in the solid material in the region adjacent to the upper half of the contour line is less than 0.8, more preferably less than 0.5, even more preferably less than 0.3, particularly preferably less than 0.1 and very particularly preferably less than 0.05.

The region of the solid material which abuts the contour line preferably has a width in the range of 0.3-1.0 μm, particularly preferably a width in the range of 0.5-0.6 μm and very particularly preferably a width of 0.5 μm. The contour line thus preferably describes the outline of the solid material, wherein the composition of the solid material (including the silver content) is determined using the method described above, preferably in a region which is limited by (i) the main boundary surface of the metal layer, (ii) the main boundary surface of the ceramic body, (iii) the contour line and (iv) a parallel shift of the contour line in the direction of the solid material by 0.3-1.0 μm, particularly preferably by 0.5-0.6 μm and very particularly preferably by 0.5 μm. The contour line is preferably divided into an upper half and a lower half halfway between the main boundary surface of the metal layer and the main boundary surface of the ceramic body, wherein the upper half of the contour line extends from the main boundary surface of the metal layer in the direction of the main boundary surface of the ceramic body and the lower half of the contour line extends from the main boundary surface of the ceramic body in the direction of the main boundary surface of the metal layer. The region of solid material to be measured therefore consists of an upper half, which lies on the upper half of the contour line, and a lower half, which lies on the lower half of the contour line.

The silver content of the solid material in the region adjacent to the upper half of the contour line and the silver content of the solid material in the region adjacent to the lower half of the contour line are preferably determined by energy dispersive X-ray spectroscopy (EDX) coupled with scanning electron microscopy (SEM) (SEM-EDX).

In SEM-EDX, a focused primary electron beam is guided (screened) over the sample surface point by point. The scattered electrons are detected using a detector, wherein the number of electrons per pixel results in a microscopic image of the sample surface in grayscale. In addition, the primary electron beam excites the sample to emit characteristic X-ray radiation, wherein the elements in the sample and their weight proportion can be determined by analyzing the energy spectrum using an EDX detector.

For the examination, for example, a scanning electron microscope (JSM-6060 SEM, JEOL Ltd) with a silicon drift EDX detector (NORAN, Thermo Scientific Inc) and analytical software (Pathfinder Mountaineer EDS System, for example Version 2.8, Thermo Scientific Inc) are used. For scanning electron microscopy, the following settings can be used: magnification: 200-fold, acceleration voltage=10 kV, working distance=10 mm, spot size (50-60) (adjusted to reach 25%+/−5% of the dead time of the EDX detector). The EDX spectrum can be detected using the following settings of the EDX detector: live time=30 s, rate=auto, low energy cutoff=100 keV, high energy cutoff=auto (per SEM acceleration voltage). Depending on the selected magnification and the thickness of the metal layer, several SEM-EDX measurements may be required to image the entire structuring region.

The silver content is measured in the region adjacent to the upper half of the contour line and in the region adjacent to the lower half of the contour line, at least at five and particularly preferably at ten representative positions within each region. The silver content is preferably understood to be the arithmetic mean of the respective individual measurements.

Surprisingly, it was found that metal-ceramic substrates with the geometry according to the invention have an increased thermal shock resistance compared to metal-ceramic substrates from the prior art. These metal-ceramic substrates comprise a high proportion of solid material in the metal layer at the boundary to the surface of the ceramic body. In contrast, it was found that the proportion of solid material in the metal layer at the boundary to the surface of the ceramic body is significantly lower in metal-ceramic substrates from the prior art, as long as they comprise a silver-comprising contact region arranged on the metal layer.

Without being bound to an explanation, this could be due to the fact that in the prior art, the metal-ceramic substrate produced is usually first structured and then silver-plated on the surface to create the contact region, wherein, however, the already structured regions of the surface of the metal-ceramic substrate are only inadequately masked during the silver-plating. For this purpose, the regions of the surface of the structured metal-ceramic substrate that are not to be coated with silver are usually masked first before the silver-plating. A film (for example a dry film) is usually used for the masking. This film spans the structuring of the metal-ceramic substrate so that the structuring is covered with the film but not completely lined, especially not in a region close to the ceramic body. The subsequent silver plating is usually done by dipping the structured and masked metal-ceramic substrate into a bath containing a solution containing silver ions. The solution containing silver ions can wash under the masking film so that it comes into direct contact with the underlying structuring. During the silver-plating process, metal ions are electrochemically dissolved from the metal layer of the metal-ceramic substrate in the region of the structuring and replaced by silver ions. It has been shown that the dissolution of metal ions from the metal layer and the deposition of silver ions occur in spatially distanced regions near the ceramic body. Therefore, silver is often deposited directly on the surface of the structuring, while the metal ions are preferably released from a region close to the ceramic body (approximately up to 50 μm distance from the ceramic body surface) so that the region of the structuring close to the ceramic body is gradually removed as the contact time with the silver-ion-containing solution progresses. This results in the removal of solid material—in particular the metal of the metal foil—from the metal foil in the region close to the ceramic body and thus creates a weak point for the detachment of the metal layer from the ceramic body, which has a detrimental effect on the thermal shock resistance. The removal of solid material in the structuring could therefore be due to a lack of lining of the structuring with the masking film. According to the invention, however, a structuring region is created which comprises sufficient amounts of solid material in the region close to the ceramic body, whereby detachment of the metal layer from the ceramic body can be prevented and an improvement in the thermal shock resistance can be achieved.

The solid material comprises silver in the region adjacent to the upper half of the contour line. The reason for this is that, according to one embodiment, the masking is applied by a printing process before the silver plating. Since the structuring of the metal-ceramic substrate usually has a curved geometry, the structuring is (almost) completely covered with the masking in a region close to the ceramic body, which improves the thermal shock resistance. In contrast, a region of the structuring further away from the ceramic body is usually not completely masked, and therefore it is at least partially coated with silver in the subsequent silver-plating step.

According to a preferred embodiment, the metal-ceramic substrate comprises a further (second) metal layer which is bonded over the surface to the ceramic body. The further metal layer is preferably bonded over the surface to the boundary surface facing away from the main boundary surface of the ceramic (and preferably running parallel thereto). The further (second) metal layer can be of the same nature as the (first) metal layer or can differ in its nature from the (first) metal layer. For the nature of the further (second) metal layer, reference is made to the above explanations for the (first) metal layer.

The metal-ceramic substrate according to the invention can in particular be used for applications in electronics, especially for the field of power electronics.

The invention therefore also provides an electronic component which comprises the metal-ceramic substrate according to the invention.

According to a preferred embodiment, the electronic component comprises the metal-ceramic substrate according to the invention and at least one chip. The at least one chip is preferably bonded over the surface to the silver-comprising contact region arranged on the (first) metal layer. Therefore, the electronic component preferably comprises a chip which is in contact with the (first) metal layer of the metal-ceramic substrate via the silver-comprising contact region.

According to a further preferred embodiment, the metal-ceramic substrate of the electronic component comprises a further (second) metal layer. The further (second) metal layer is preferably bonded over the surface to the ceramic body. In this case, the further metal layer is preferably bonded over the surface to the boundary surface of the ceramic body facing away from the main boundary surface of the ceramic body (and preferably running parallel thereto).

According to a further preferred embodiment, the electronic component comprises a base plate. Said base plate is preferably bonded over the surface to the further (second) metal layer of the metal-ceramic substrate. Alternatively, the further (second) metal layer of the metal-ceramic substrate can be formed as a heat sink.

According to a further preferred embodiment, the electronic component comprises a metal-ceramic substrate which comprises a (first) metal layer and a further (second) metal layer (wherein the further metal layer is preferably bonded over the surface to the boundary surface facing away from the main boundary surface of the ceramic body), a base plate and at least one chip, wherein the at least one chip is bonded over the surface to the first metal layer of the metal-ceramic substrate via the silver-comprising contact region arranged on the metal layer and the base plate is bonded over the surface to the further (second) metal layer of the metal-ceramic substrate.

The metal-ceramic substrate according to the invention can be obtained by different manufacturing processes.

According to a preferred embodiment, the method is a method for producing a metal-ceramic substrate provided with a structuring and a contact region comprising silver, said method comprising the steps of:
a) providing a metal-ceramic substrate comprising
   a1) a ceramic body, and
   a2) a metal layer bonded over the surface to the ceramic body,
b) structuring the metal layer,
c) applying a masking to the structured metal layer by applying a liquid medium comprising a masking agent to the structured metal layer in regions and solidifying the masking agent,
d) depositing a silver-containing layer on the unmasked regions of the structured metal layer to obtain a silver-comprising contact region, and
e) removing the masking.

In step a), therefore, a metal-ceramic substrate is preferably first provided.

This metal-ceramic substrate comprises a ceramic body and a metal layer that is bonded over the surface to the ceramic body. The metal-ceramic substrate can be a standard metal-ceramic substrate. The ceramic body and the metal layer may have a composition as described above with respect to the metal-ceramic substrate. The metal layer can preferably be cohesively bonded to the ceramic body, as also described above with respect to the metal-ceramic substrate.

In step b), the metal layer is preferably first structured.

Structuring is preferably understood to mean recesses in the metal layer in order to separate individual portions of the metal layer from one another and thus to electrically isolate them. The structuring therefore preferably exposes regions of the ceramic body. Such structuring is usually created using etching techniques. For example, an etching mask can first be applied to the metal layer. The etching mask serves to protect the masked regions of the metal layer of the metal-ceramic substrate from etching in an etching step. This ensures that only those regions of the metal layer of the metal-ceramic substrate that are unmasked and intended for structuring are accessible for etching. Consequently, the etching masking is created in such a way that no etching of the masked regions of the metal layer occurs in the etching step. The type of etching mask is not limited further. The etching mask can, for example, be a standard negative mask or positive mask. Standard etching resists can be used to produce the etching mask. These etch resists preferably contain a curable polymer (for example a light-curable polymer) and can be applied to the metal layer, for example, as a film (for example as a dry film) or as a liquid (for example by printing or spraying). After application, the etch resists can be treated in a suitable manner (e.g., cured by light irradiation) to obtain the etching mask. According to one possible embodiment, a photosensitive film is applied to the metal layer of the metal-ceramic substrate and is then exposed at the regions to be masked in order to obtain the etching mask. The unexposed regions of the photosensitive film can then be removed in a conventional manner (for example using a sodium carbonate solution). After the etching mask has been applied to the metal layer, unmasked regions of the metal layer are preferably etched to obtain a structuring. Etching is preferably carried out in a standard professional manner. Etching is therefore preferably carried out using a standard etching solution. According to a preferred embodiment, the etching solution is selected from the group consisting of FeCl₃ etching solutions and CuCl₂ etching solutions. If necessary, an additional etching solution can be used, for example to structure unmasked regions of an optionally contained bonding layer. According to a preferred embodiment, the further etching solution can be selected from the group consisting of etching solutions containing hydrogen peroxide and etching solutions containing ammonium peroxodisulfate. For example, the further etching solution may be an etching solution containing ammonium fluoride and fluoroboric acid (for example HBF₄) as well as hydrogen peroxide and/or ammonium peroxodisulfate.

Preferably, after etching unmasked regions of the metal layer while maintaining a structuring, the etching mask is removed. The etching mask can be removed in a standard manner. For this purpose, the metal-ceramic substrate can be treated with an alkaline solution (e.g., a 2.5% sodium hydroxide solution) to remove the etching mask.

In step c), a masking is preferably applied to the structured metal layer by applying a liquid medium comprising a masking agent to the structured metal layer in regions and solidifying the masking agent.

The masking serves to protect the masked regions of the metal layer from deposition of a silver-containing layer in step d). This ensures that a silver-containing layer is deposited only on the unmasked regions of the metal layer of the metal-ceramic substrate. Consequently, the masking is designed in such a way that no silver-containing layer can be deposited on the masked regions of the metal layer of the metal-ceramic substrate.

According to a preferred embodiment, the structured metal layer to which the masking is applied also comprises the structuring region, particularly preferably the structuring region between the main boundary surface of the metal layer and the main boundary surface of the ceramic. Thus, in particular, the regions of the metal layer in the vicinity of the ceramic body are also provided with a masking in order to protect them from dissolution during the deposition of a silver-containing layer, in particular upon contact with a solution containing silver ions, in step d).

To apply the masking, a liquid medium comprising a masking agent is applied to the structured metal layer in regions and the masking agent is solidified.

The liquid medium is preferably a medium that is liquid at room temperature and normal pressure. The liquid medium is preferably a medium comprising a polar solvent, particularly preferably water. According to a preferred embodiment, the liquid medium is selected from the group consisting of solutions and suspensions.

The liquid medium comprises a masking agent. The masking agent is preferably designed so that it can be solidified. The masking agent is not further restricted. According to a preferred embodiment, the masking agent is curable, in particular UV-curable. The UV-curable masking agent preferably comprises at least one compound which is selected from the group consisting of monomers and oligomers. According to a particularly preferred embodiment, the UV-curable masking agent comprises at least one compound selected from the group consisting of acrylates, epoxies and unsaturated polyester resins. The liquid medium preferably further comprises a photoinitiator. The photoinitiator may, for example, be a compound that decomposes upon absorption of UV light and forms a reactive species capable of initiating the polymerization and curing of the UV-curable masking agent. In addition, the liquid medium may contain other components such as colorants and additives.

The liquid medium, which contains a masking agent, is applied to the structured metal layer in regions. For this purpose, the liquid medium is preferably applied to the regions of the structured metal layer that are to be masked and protected from the deposition of a silver-containing layer in step d).

The liquid medium is preferably applied to the structured metal layer by printing, spraying or painting. According to a particularly preferred embodiment, the liquid medium is applied by printing using an inkjet process.

After application of the liquid medium, the masking agent contained therein is preferably solidified. For this purpose, the masking agent is preferably cured. Curing can be achieved, for example, by irradiating the liquid medium with UV light so that the masking agents contained in the liquid medium (in particular monomers or oligomers) polymerize.

According to a preferred embodiment, the application of the masking to the structured metal layer comprises an additive masking step. The additive masking step means the application of a masking agent. According to a further preferred embodiment, the application of the masking to the structured metal layer does not comprise a subtractive masking step. A subtractive masking step is understood to mean the partial removal of masking agent applied and solidified, for example in an additive masking step, in particular before the deposition of a silver-containing layer on the unmasked regions of the structured metal layer to obtain a silver-comprising contact region according to step d). According to this preferred embodiment, the liquid medium comprising the masking agent is applied only to the regions of the structured metal layer and, if appropriate, regions of the ceramic body which are exposed by the recesses in the metal layer forming the structuring, onto which no silver-containing layer is deposited in step d). In conventional masking methods, masking agent is applied to the structured metal layer, preferably as a layer, in particular over the entire surface, in an additive masking step, wherein in a subsequent subtractive masking step the solidified masking agent is removed in the regions of the structured metal layer onto which a silver-containing layer is deposited in a subsequent step. By omitting a subtractive masking step, according to this preferred embodiment, a particularly simple method for producing a metal-ceramic substrate provided with a structuring and a silver-comprising contact region is advantageously provided.

According to a preferred embodiment, in step c) a mask is also applied to regions of the ceramic body which are exposed by the recesses in the metal layer forming the structuring, by applying a liquid medium comprising a masking agent to regions of the ceramic body, in particular to regions of the ceramic body which are exposed by the recesses in the metal layer forming the structuring, and solidifying the masking agent. Applying a masking to exposed regions of the ceramic body may be advantageous in order to protect the exposed regions of the ceramic body in step d) from deposition of a silver-containing layer.

The application of a masking to the structured metal layer and the application of a masking to regions of the ceramic body that are exposed by the recesses in the metal layer that form the structuring can be carried out simultaneously or sequentially.

For applying a masking to regions of the ceramic body which are exposed by the recesses in the metal layer forming the structuring, a liquid medium as described above with respect to the application of a masking to the structured metal layer and an application as described above with respect to the application of a masking to the structured metal layer can be used.

In step d), a silver-containing layer is preferably deposited on the unmasked regions of the structured metal layer to obtain a silver-comprising contact region.

The silver-containing layer is preferably a layer consisting of silver or a silver-containing alloy, particularly preferably silver. The deposition of the silver-containing layer is preferably carried out chemically (for example electrochemically) or physically. The chemical deposition of the silver-containing layer can be carried out, for example, galvanically or currentlessly. Preference is given to chemical deposition of the silver-containing layer currentlessly by applying a silver-containing solution with a charge exchange between the metals, wherein metal of the metal layer partially dissolves while the silver in solution is deposited. According to a preferred embodiment, the silver-containing solution contains a silver salt and particularly preferably silver nitrate. According to a particularly preferred embodiment, the silver-containing solution is an acidic solution of silver nitrate and particularly preferably a nitric acid solution of silver nitrate. The concentration of silver in the nitric acid solution can, for example, be in the range of 0.5-1.5 g/l, particularly preferably in the range of 0.6-1.4 g/l and very particularly preferably in the range of 0.8-1.2 g/l. The physical deposition of the silver-containing layer can be carried out, for example, by gas phase deposition. Preferred methods for gas phase deposition are in particular electron beam deposition, laser beam deposition, arc discharge deposition or cathode sputtering.

In step e), the masking is preferably removed.

The masking can be removed in a standard manner. For this purpose, the masking can be exposed, for example, to an alkaline solution (for example a 2.5% sodium hydroxide solution). After removal of the masking, the metal-ceramic substrate comprises at least one silver-comprising contact region, wherein the surface of the metal layer not provided with the silver-comprising contact region is freely accessible.

The method described herein makes it possible to obtain a metal-ceramic substrate which is provided with a structure and a contact region comprising silver. By creating a silver-comprising contact region, the chip can be more easily connected to the metal-ceramic substrate using common processes such as sintering or soldering. The metal-ceramic substrate obtained in this way is characterized by a particularly high resistance to thermal shock.

### EXEMPLARY EMBODIMENTS

The present invention is described in more detail below by means of exemplary embodiments, which, however, should not be understood as limiting.

### Example 1

### Example 1a—Preparation of a Structured Metal-Ceramic Substrate

For Example 1, a copper-ceramic substrate was used in which a ceramic body made of a silicon nitride ceramic with the dimensions 177.8×139×0.32 mm was bonded on both sides to a copper layer with the dimensions 170×132×0.3 mm using an AMB (Active Metal Brazing) process. This copper-ceramic substrate was first cleaned after production.

A photosensitive film was then applied to both copper layers of the copper-ceramic substrate using a hot roll laminator. The photosensitive film was exposed to 30 mJ/cm² in each of the regions to be masked in order to cure the polymer contained in the photosensitive film and obtain an etching mask. Subsequently, the unexposed regions of the photosensitive film were removed wet-chemically using a sodium carbonate solution (concentration=10 g/l). After applying the etching mask, the copper-ceramic substrate was cleaned by rinsing. Subsequently, the unmasked regions of the copper layers of the copper-ceramic substrate were wet-chemically etched. For this purpose, the copper-ceramic substrate was sprayed in an etching system with a hydrochloric acid copper chloride solution (copper ion content=160 g/l) containing hydrogen peroxide. Etching was carried out at a temperature of 50° C. and a spray pressure of 2.8 bar. By etching, material was removed from the unmasked regions of the copper layers of the copper-ceramic substrate. The copper-ceramic substrates were then rinsed. Then, unmasked areas of the bonding layer contained in the copper-ceramic substrate were also wet-chemically etched. For this purpose, the copper-ceramic substrate was again sprayed in an etching system with an etching solution containing ammonium fluoride, fluoroboric acid and hydrogen peroxide. The copper-ceramic substrate was then rinsed and dried. The etching mask was then removed in a stripping system using a 2.5% sodium hydroxide solution.

### Example 1b—Preparation of a Structured Metal-Ceramic Substrate with a Silver-Comprising Contact Region

The structured copper-ceramic substrate prepared in Example 1a was provided with a silver-comprising contact region. For this purpose, a masking was first applied to a structured copper layer of the copper-ceramic substrate (including the structuring region) and regions of the ceramic body that were exposed by the recesses in the copper layer that form the structuring (exposed regions of the ceramic body). For this purpose, the structured copper-ceramic substrate was positioned in an inkjet printer (MicroCraft C4K7861T, Sense Advanced Technology GmbH) to apply a masking to the structured copper layer (including the structuring region) and the exposed regions of the ceramic body. The regions of the structured copper layer that were to remain free of silver as well as exposed regions of the ceramic body in the structuring regions were printed with a liquid medium containing a masking agent (DiPaMAT Etch Resist ER02). The masking agent was then cured using UV radiation (LED 390 nm, 500 mJ/cm²). Consequently, the regions of the structured copper layer that were to remain free of silver as well as the exposed regions of the ceramic body were covered with a 30 μm thick masking.

Subsequently, silver-containing contact regions were deposited on the unmasked regions of the copper layer of the copper-ceramic substrate. For this purpose, the copper-ceramic substrate provided with the masking was first pretreated with a first solution containing hydrogen peroxide and sulfuric acid and then contacted with a nitric acid silver nitrate solution (silver content=1.0 g/l). After deposition of the silver-containing contact regions, the copper-ceramic substrate was carefully rinsed with water to remove any residues. The masking was then removed in a stripping system using a 2.5% sodium hydroxide solution.

The resulting copper-ceramic substrate was laser cut into individual parts with the dimensions (20.5×17.0 mm) and could then be used for further investigations and the production of an electronic component.

### Comparative Example 1

### Comparative Example 1a—Preparation of a Structured Metal-Ceramic Substrate

In Comparative Example 1a, a structured copper-ceramic substrate was prepared analogously to Example 1a.

### Comparative Example 1b—Preparation of a Structured Metal-Ceramic Substrate with a Silver-Comprising Contact Region

The structured copper-ceramic substrate prepared in Comparative Example 1a was provided with a silver-comprising contact region. For this purpose, a masking was first applied to a structured copper layer of the copper-ceramic substrate. For this purpose, a photosensitive film was applied to both etched surfaces of the structured copper-ceramic substrate using a hot roll laminator. The photosensitive film was exposed to 30 mJ/cm² in each of the regions to be masked in order to cure the polymer contained in the photosensitive film and obtain the masking. The unexposed points of the photosensitive film were then removed wet-chemically using a sodium carbonate solution (concentration=10 g/l). After applying the masking, the copper-ceramic substrate was again cleaned by rinsing. Subsequently, silver-containing contact regions were deposited on the unmasked regions of the copper layer of the copper-ceramic substrate. For this purpose, the copper-ceramic substrate provided with the masking was first pretreated with a first solution containing hydrogen peroxide and sulfuric acid and then contacted with a nitric acid silver nitrate solution (silver content=1.0 g/l). After deposition of the silver-containing contact regions, the copper-ceramic substrate was carefully rinsed with water to remove any residues. The masking was then removed in a stripping system using a 2.5% sodium hydroxide solution.

The resulting copper-ceramic substrate was laser cut into individual parts with the dimensions (20.5×17.0 mm) and could then be used for further investigations and the production of an electronic component.

### Evaluation:

For the copper-ceramic substrates obtained in Example 1 and in Comparative Example 1, the ratio A (BCD_{solid})/A (BCDₜₒₜₐₗ) was determined. For this purpose, as described herein, the copper-ceramic substrates were cut perpendicular to the main boundary surface of the respective ceramic bodies and images of the cross-sections thus obtained were taken using a light microscope. Points A, B, C and D were determined in the cross-sections. Then, the ratio A (BCD_{solid})/A (BCDₜₒₜₐₗ) was determined for each of the copper-ceramic substrates. For this purpose, ten different cross-sections of structuring regions in the copper layer of the respective copper-ceramic substrate were investigated, the ratio A (BCD_{solid})/A (BCDₜₒₜₐₗ) for each of these cross-sections was determined, and the mean of the ratios A (BCD_{solid})/A (BCDₜₒₜₐₗ) for each of these cross-sections was calculated to arrive at the ratio A (BCD_{solid})/A (BCDₜₒₜₐₗ) for the respective copper-ceramic substrate. Furthermore, the standard deviation SSD was determined.

Likewise, for the copper-ceramic substrates obtained in Example 1 and Comparative Example 1, the silver content in the region adjacent to the upper half of the contour line and in the region adjacent to the lower half of the contour line was determined by energy dispersive X-ray spectroscopy (EDX) coupled with scanning electron microscopy (SEM) as described above (SEM-EDX).

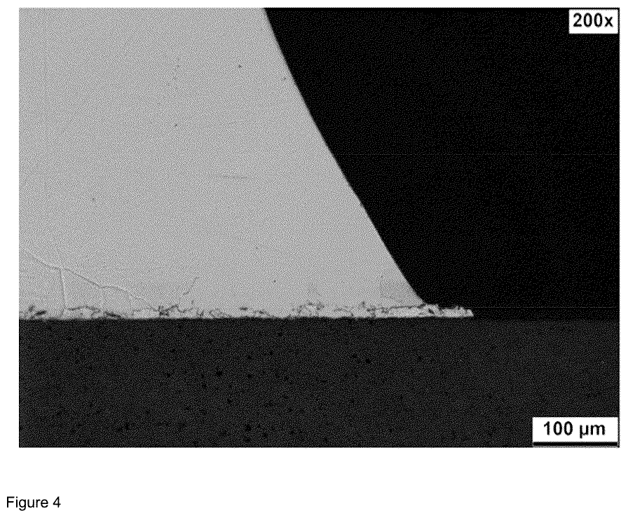

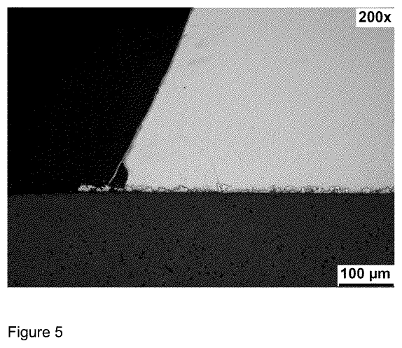

FIG. 4 shows an example of a light microscopic image of the cross-section of a detail of structuring region of the copper layer of a copper-ceramic substrate according to Example 1, while FIG. 5 shows an example of a light microscopic image of the cross-section of a detail of a structuring region of the copper layer of a copper-ceramic substrate according to Comparative Example 1.

The results are shown in Table 1.

TABLE 1

| | | Standard | Silver | Silver | |
|---|---|---|---|---|---|
| | A (BCD_{solid})/ | deviation | content | content | |
| | A (BCDₜₒₜₐₗ) | SSD | upper half | lower half | |
| Example 1 | 97.9% | 0.4% | 83 wt. % | 1 | wt. % |
| Comparative | 67.3% | 11.7% | 76 wt. % | 81 | wt. % |
| Example 1 | | | | | |

The copper-ceramic substrates were tested for their thermal shock resistance. For this purpose, thermal shock resistance tests were carried out.

### Thermal Shock Resistance Test:

In preparation for the thermal shock resistance test, ultrasound microscopy (PVA Tepla SAM300) was first used to check whether the copper-ceramic substrates were in perfect condition. For the test, only copper metal-ceramic substrates were used that showed no delamination between the ceramic body and copper layer or other deformations that could lead to delamination of the copper layer from the ceramic body (e.g., cracks). To test the thermal shock resistance, the copper-ceramic substrates were repeatedly exposed to a cold liquid (temperature−65° C., Galden Do2TS) and a hot liquid (temperature+150° C., Galden Do2TS) in a cycling chamber (ESPEC TSB-21 51) for a period of five minutes each. The copper-ceramic substrates were checked again every 1000 cycles for delamination and other deformations by means of ultrasound microscopy (PVA Tepla SAM300). The test was terminated after 3000 cycles. The copper-ceramic substrates were then again examined for delamination and other deformations by means of ultrasound microscopy (PVA Tepla SAM300). The condition of the respective copper-ceramic substrates after the thermal shock resistance test was compared with the condition of the copper-ceramic substrates before the thermal shock resistance test with regard to delamination and other deformations. Delaminations and other deformations (e.g., cracks) were visible as white discolorations in the ultrasound image.

The results are shown in Table 2.

TABLE 2

| | Result of the thermal shock resistance test |
|---|---|
| Example 1 | Very good: No delaminations were visible |
| Comparative | Poor: Pronounced delaminations were visible at the corners |
| Example 1 | of the copper-ceramic substrate |

The results show that the metal-ceramic substrate according to the invention is clearly superior to the metal-ceramic substrate of Comparative Example 1 with regard to thermal shock resistance.

### LIST OF REFERENCE NUMERALS

1 metal-ceramic substrate
4 structuring region
8 contact region
10 ceramic body
15 main boundary surface of the ceramic body
20 metal layer
22 recess
24 main boundary surface of the metal layer
40 contour line
50 solid material
60 silver
200 further metal layer

1. A metal-ceramic substrate comprising
a) a ceramic body which comprises a main boundary surface,
b) a metal layer which comprises a main boundary surface, wherein the metal layer is bonded over the surface to the ceramic body, and wherein the metal layer comprises a structuring region which comprises
(i) solid material in regions and
(ii) non-solid material in regions
and
c) a silver-comprising contact region arranged on the metal layer, wherein, in a cross-section through the metal-ceramic substrate perpendicular to the main boundary surface of the ceramic body, the structuring region has a geometry that satisfies the following requirement:
$$A ( {BCD}_{s o l i d} ) / A ( {BCD}_{t otal} ) > 70 \% ,$$
where
A (BCDₜₒₜₐₗ) is the total area of the triangle described by the points B, C and D, and
A (BCD_{solid}) is the area of the triangle described by the points B, C and D that is occupied by solid material,
wherein points B, C and D are determined as follows:
1. the best-fit line between the ceramic body and the metal layer is determined;
2. the contour line is determined that separates the solid material from the non-solid material;
3. on a perpendicular to the best-fit line, at a distance of 150 μm from the best-fit line, point A is determined at which the perpendicular to the best-fit line intersects the contour line;
4. on a perpendicular to the best-fit line, at a distance of 80 μm from the best-fit line, point B is determined at which the perpendicular to the best-fit line intersects the contour line;
5. on a straight line passing through points A and B, point C is determined at which the straight line intersects the best-fit line; and
6. on a perpendicular to the best-fit line, which passes through point B, point D is determined at which the perpendicular intersects the best-fit line; and wherein the contour line extends from the main boundary surface of the metal layer to the main boundary surface of the ceramic body, wherein the contour line comprises an upper half and a lower half, wherein the upper half of the contour line extends from the main boundary surface of the metal layer towards the main boundary surface of the ceramic body and the lower half of the contour line extends from the main boundary surface of the ceramic body towards the main boundary surface of the metal layer, and wherein the solid material in the region adjacent to the upper half of the contour line has a higher silver content than in the region adjacent to the lower half of the contour line.

2. The metal-ceramic substrate according to claim 1, wherein the ceramic of the ceramic body is selected from the group consisting of aluminum nitride ceramics, silicon nitride ceramics, and aluminum oxide ceramics.

3. The metal-ceramic substrate according to claim 1, wherein the metal layer comprises copper.

4. The metal-ceramic substrate according to claim 1, wherein the solid material contains metal of the metal layer.

5. The metal-ceramic substrate according to claim 1, wherein the non-solid material contains gaseous material.

6. The metal-ceramic substrate according to claim 1, wherein the following requirement is met:
$$A ( {BCD}_{s o l i d} ) / A ( {BCD}_{total} ) > 95 \% .$$

7. The metal-ceramic substrate according to claim 1, wherein the sample standard deviation SSD of the ratio A (BCD_{solid})/A (BCDₜₒₜₐₗ) over at least ten different cross-sections of the structuring region of the metal layer is not more than 10%.

8. The metal-ceramic substrate according to claim 1, wherein the ratio of the content of silver in the solid material in the region adjacent to the lower half of the contour line to the content of silver in the solid material in the region adjacent to the upper half of the contour line is less than 0.8.

9. An electronic component comprising a metal-ceramic substrate according to claim 1.
